(19) United States
(12) Patent Application Publication
(10) Pub. No.: US 2016/0064194 A1
(43) Pub. Date: Mar. 3, 2016

(54) SEMICONDUCTOR FABRICATING APPARATUS AND METHOD OF FABRICATING SEMICONDUCTOR DEVICE USING THE SAME

(71) Applicants: KEN TOKASHIKI, Seongnam-si (KR); Sungil CHO, Seoul (KR); Kyungho JANG, Hwaseong-si (KR)

(72) Inventors: KEN TOKASHIKI, Seongnam-si (KR); Sungil CHO, Seoul (KR); Kyungho JANG, Hwaseong-si (KR)

(21) Appl. No.: 14/844,057

(22) Filed: Sep. 3, 2015

(30) Foreign Application Priority Data
Sep. 3, 2014 (KR) 10-2014-0117227

(51) Int. Cl. H01J 37/32; H01L 21/683; H01L 21/67

(52) U.S. Cl. CPC H01J 37/32183; H01L 21/67069; H01L 21/6831; H01J 37/32091; H01J 37/32165; H01J 37/32697; H01J 37/3244; H01J 2237/334

(57) ABSTRACT

The disclosure provides a semiconductor fabricating apparatus and a method of fabricating a semiconductor device using the same. In some embodiments, the apparatus may synchronize low-frequency, high-frequency and direct current (DC) powers that are applied to an electrode. The low-frequency power may have a non-sinusoidal waveform. Thus, reliability and reproducibility of a semiconductor fabrication process may be improved. In other embodiments, the apparatus may include a first low-frequency power generator generating a first low-frequency power having a sinusoidal waveform and a second low-frequency power generator generating a second low-frequency power having a non-sinusoidal waveform.

### CROSS-REFERENCE TO RELATED APPLICATION

This U.S. non-provisional patent application claims priority under 35 U.S.C. §119 to Korean Patent Application No. 10-2014-0117227, filed on Sep. 3, 2014 in the Korean Intellectual Property Office, the disclosure of which is hereby incorporated by reference in its entirety.

### BACKGROUND

The disclosure relates to a semiconductor fabricating apparatus and a method of fabricating a semiconductor device using the same.

Semiconductor devices are widely used in an electronic industry because of their small sizes, multi-functional characteristics, and/or low fabricating costs. Semiconductor devices may be fabricated using various semiconductor fabricating processes, such as deposition, ion implantation, photolithography, and etching. As semiconductor devices have been highly integrated, sizes of patterns constituting semiconductor devices have been reduced and aspect ratios of the patterns have been increased. The size reduction and/or the aspect ratio increase of the patterns may cause various problems with the semiconductor fabricating processes that use plasma.

### SUMMARY

Embodiments of the disclosure may provide a semiconductor fabricating apparatus capable of improving reliability of a semiconductor fabricating process and a method of fabricating a semiconductor device using the same.

Embodiments of the disclosure may also provide a semiconductor fabricating apparatus capable of effectively etching an opening with a high aspect ratio and a method of fabricating a semiconductor device using the same.

In one aspect, a semiconductor fabricating apparatus may include: a process chamber having an inner, enclosed region in which a semiconductor fabrication process is performed; a lower electrode disposed in the process chamber having external connections and having a top surface on which a substrate is loaded; an upper electrode disposed over the lower electrode in the process chamber having external connections; a low-frequency power generator connected to the lower electrode and generating a low-frequency power having a non-sinusoidal waveform; a high-frequency power generator generating a high-frequency power at a frequency higher than a frequency of the low-frequency power generator; and a direct current (DC) power generator generating a DC power with a period having a first level (e.g. voltage level) duration and a second level duration. When the semiconductor fabrication process is performed, the DC power generator may apply a first DC voltage to the upper electrode during the first level duration and may apply a second DC voltage different from the first DC voltage to the upper electrode during the second level duration. When the semiconductor fabrication process is performed, the high-frequency power and the low-frequency power may be turned-on during the first level duration and may be turned-off during the second level duration.

In some embodiments, the semiconductor fabricating apparatus may further include: a blocking capacitor connected between the lower electrode and the low-frequency power generator and between the lower electrode and the high-frequency power generator. The low-frequency power generator and the high-frequency power generator may be connected to the lower electrode through the blocking capacitor. A controller may be connected to the low-frequency power generator, the high-frequency power generator, and the DC power generator. The controller may provide control signals to the power generators to thereby control them and in some embodiments to synchronize them.

The semiconductor fabrication process may be an etching process.

In some embodiments, a period of the low-frequency power may have a first transition duration, a low-level (e.g. low voltage level) duration, a second transition duration, and a high-level (e.g. high voltage level) duration. A low-level voltage may be applied during the low-level duration, and a high-level voltage higher than the low-level voltage may be applied during the high-level duration. A time length of the low-level duration may be different from a time length of the high-level duration. For example, the time length of the low-level duration may be between two and five times the time length of the high-level duration.

In some embodiments, the low-level voltage may be constant during the low-level duration.

In some embodiments, the low-level voltage may be gradually varied during the low-level duration.

In some embodiments, the first and second DC voltages may be negative voltages, and the second DC voltage may be lower than the first DC voltage.

In some embodiments, the semiconductor fabricating apparatus may further include: a band-pass filtering unit connected between the low-frequency power generator and the lower electrode; and a low-frequency matching unit connected between the band-pass filtering unit and the lower electrode. The band-pass filtering unit may include a plurality of band-pass filters, and each of the band-pass filters may include a coil and a capacitor that are connected in series to each other. The capacitors of the band-pass filters may have capacitance values different from each other, and the low-frequency matching unit may include a plurality of matching circuits connected to the plurality of band-pass filters, respectively. In some embodiments a fast Fourier transform circuit may be connected between the low-frequency power generator and the band-pass filtering unit.

An absolute value of the low-level voltage applied to the substrate may be greater than an absolute value of a high-level voltage applied to the substrate.

In another aspect, a semiconductor fabricating apparatus may include: a process chamber; a lower electrode disposed in the process chamber and having a top surface on which a substrate is loaded; an upper electrode disposed over the lower electrode in the process chamber; a first low-frequency power generator connected to the lower electrode and generating a first low-frequency power having a sinusoidal waveform, the first low-frequency power used in a first semiconductor process; a second low-frequency power generator connected to the lower electrode and generating a second low-frequency power having a non-sinusoidal waveform, the second low-frequency power used in a second semiconductor process; and a high-frequency power generator generating a high-frequency power of which a frequency is higher than frequencies of the first and second low-frequency powers. The high-frequency power may be applied to generate plasma over the lower electrode during each of the first and second semiconductor processes.

In some embodiments, the first low-frequency power may be interrupted by initiation of the second semiconductor process, and the second low-frequency power may be interrupted by initiation of the first semiconductor process. When interrupted the power output from the first or second low-frequency power generator may turn off. The power output from the first or second low-frequency power generator may be set to zero volts with zero frequency for a certain duration of time.

In some embodiments, the first semiconductor process may be a first etching process, and the second semiconductor process may be a second etching process. The first and second etching processes may be performed in-situ in the same process chamber, e.g., without a vacuum break.

In some embodiments, the semiconductor fabricating apparatus may further include: a blocking capacitor connected between the lower electrode and the first low-frequency power generator, between the lower electrode and the second low-frequency power generator, and between the lower electrode and the high-frequency power generator. The first low-frequency power generator, the second low-frequency power generator, and the high-frequency power generator may be connected to the lower electrode through the blocking capacitor.

In some embodiments, the semiconductor fabricating apparatus may further include: a direct current (DC) power generator generating a DC power of which a DC period has a first level duration and a second level duration. When each of the first and second semiconductor processes is performed, the DC power may apply a first DC voltage to the upper electrode during the first level duration and may apply a second DC voltage different from the first DC voltage to the upper electrode during the second level duration.

In some embodiments, the lower electrode may further include an electrostatic chuck (ESC), and the upper electrode may further include a shower head to supply a process gas into the process chamber. In some embodiments, the first and second semiconductor fabrication processes may further comprise use of a carrier gas, where the carrier gas is argon (Ar). In some embodiments, the first etching process and the second etching process are performed at the same time.

In some embodiments, when the first semiconductor process is performed, the first low-frequency power and the high-frequency power may be turned-on during the first level duration and may be turned-off during the second level duration. When the second semiconductor process is performed, the second low-frequency power and the high-frequency power may be turned-on during the first level duration and may be turned-off during the second level duration.

In some embodiments, a period of the second low-frequency power may have a first transition duration, a low-level duration, a second transition duration, and a high-level duration. A linear low-level voltage may be applied during the low-level duration, and a linear high-level voltage higher than the linear low-level voltage may be applied during the high-level duration. A time length of the low-level duration may be different from a time length of the high-level duration.

In some embodiments, the semiconductor fabricating apparatus may further include: a band-pass filtering unit connected between the second low-frequency power generator and the lower electrode; and a matching unit connected between the band-pass filtering unit and the lower electrode. The band-pass filtering unit may include a plurality of band-pass filters, and each of the band-pass filters may include a coil and a capacitor that are connected in series to each other. The capacitors of the band-pass filters may have capacitance values different from each other. The matching unit may include a plurality of matching circuits connected to the plurality of band-pass filters, respectively.

The matching units may each be configured to improve a transmission efficiency of the power that passes through them, e.g. to improve each of the high-frequency, first low-frequency, and second low-frequency powers. In some embodiments, a frequency of the first low-frequency power may be in a range of 100 Hz to 3.3 MHz, a frequency of the second low-frequency power may be in a range of 100 Hz to 3.3 MHz, and a frequency of the high-frequency power may be a radio frequency (RF) in a range of 13 MHz to 200 MHz.

In still another aspect, a method of fabricating a semiconductor device may include: loading a substrate having an etch target layer on a lower electrode in a process chamber; performing a first etching process on the etch target layer by applying a first low-frequency power having a sinusoidal waveform and a high-frequency power; and performing a second etching process on the etch target layer by applying a second low-frequency power having a non-sinusoidal waveform and the high-frequency power. A frequency of the high-frequency power may be higher than frequencies of the first and second low-frequency powers.

In some embodiments, the first low-frequency power may be interrupted during the second etching process, and the second low-frequency power may be interrupted during the first etching process.

In some embodiments, a direct current (DC) power may be applied to an upper electrode disposed over the substrate during each of the first and second etching processes. A period of the DC power may have a first level duration and a second level duration. The DC power may apply a first DC voltage to the upper electrode during the first level duration and may apply a second DC voltage different from the first DC voltage to the upper electrode during the second level duration.

In some embodiments, when the first etching process is performed, the first low-frequency power and the high-frequency power may be turned-on during the first level duration and may be turned-off during the second level duration. When the second etching process is performed, the second low-frequency power and the high-frequency power may be turned-on during the first level duration and may be turned-off during the second level duration.

In some embodiments, the first etching process and the second etching process may be alternately and/or repeatedly performed.

In some embodiments, the second etching process may comprise application of a low-level voltage of the second low-frequency power through a blocking capacitor, where an absolute value of the low-level voltage of the power in the substrate may be greater than an absolute value of a high-level voltage of the power in the substrate.

In some embodiments, the first frequency may be in a range of 100 Hz to 3.3 MHz, the second frequency may be in a range of 100 Hz to 3.3 MHz, and the third frequency may be a radio frequency (RF) in a range of 13 MHz to 200 MHz.

In another aspect, a method of fabricating a semiconductor device may comprise loading a substrate on a first electrode in a process chamber and then repetitively applying a direct current (DC) power to a second electrode of the process chamber. The method may further include repetitively performing a first etching process by applying plasma to the substrate and a first low-frequency power having a non-sinusoidal waveform through a first low frequency matching circuit to the first electrode. The method may further include repetitively performing a second etching process by applying plasma to the substrate and a second low-frequency power having a sinusoidal waveform through a second low frequency matching circuit to the first electrode. In this example method, a period of the DC power may be equal in duration to each of the first and second etching processes and sequentially comprise application of a first DC voltage and a second DC voltage lower than the first DC voltage. In some embodiments, the first and second low-frequency powers may be turned-off during application of the second DC voltage.

In an exemplary embodiment a period of the first low-frequency power may sequentially comprise a first transition duration, a low-level duration where a gradually varying low-level voltage is applied, a second transition duration, and a high-level duration where a linear high-level voltage, higher than the gradually varying low-level voltage, is applied.

In some embodiments, the first low-frequency power may be generated by combining a plurality of sinusoidal powers having different frequencies and different amplitudes from each other.

In some embodiments, the first and second etching processes are performed in-situ. The first etching process and the second etching process may be performed sequentially or at the same time.

### BRIEF DESCRIPTION OF THE DRAWINGS

FIG. 1 is a schematic diagram illustrating a semiconductor fabricating apparatus according to some embodiments of the disclosure;

FIG. 2 is a schematic diagram illustrating a low-frequency power generator, a band-pass filtering unit, and a low-frequency matching unit of FIG. 1;

FIG. 3 is a graph illustrating an embodiment of a waveform of a low-frequency power that may be generated from the low-frequency power generator of FIG. 1;

FIG. 4 is a graph illustrating another embodiment of a waveform of a low-frequency power that may be generated from the low-frequency power generator of FIG. 1;

FIG. 5 is a graph illustrating still another embodiment of a waveform of a low-frequency power that may be generated from the low-frequency power generator of FIG. 1;

FIG. 6 is a graph illustrating powers that may be generated from power generators of FIG. 1 and a power that may be generated in a substrate by the power generators to explain a method of operating the semiconductor fabricating apparatus of FIG. 1;

FIG. 7 is a schematic block diagram illustrating a direct current (DC) power generator of FIG. 1;

FIG. 8 is a graph illustrating an exemplary method of operating the DC power generator of FIG. 7;

FIG. 9 is a schematic diagram illustrating a semiconductor fabricating apparatus according to other embodiments of the disclosure;

FIGS. 10 and 11 are graphs illustrating powers that may be generated from power generators of FIG. 9 and a power generated in a substrate by the power generators to explain a method of operating the semiconductor fabricating apparatus of FIG. 9;

FIGS. 12 to 16 are cross-sectional views illustrating an exemplary method of fabricating a semiconductor device according to some embodiments of the disclosure;

FIG. 17 is a flowchart illustrating an exemplary method of performing a semiconductor fabrication process using the semiconductor fabricating apparatus of FIG. 9 in methods of fabricating a semiconductor device according to embodiments of the disclosure; and

FIGS. 18 to 24 are cross-sectional views illustrating an exemplary method of fabricating a semiconductor device according to other embodiments of the disclosure.

### DETAILED DESCRIPTION OF THE EMBODIMENTS

The disclosure will now be described more fully hereinafter with reference to the accompanying drawings, in which example embodiments set forth herein. These example embodiments are just that—examples—and many implementations and variations are possible that do not require the details provided herein. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be also understood that although the terms first, second, third etc. may be used herein to describe various elements, these elements should not be limited by these terms. These terms are only used to distinguish one element from another element. Thus, a first element referenced in some embodiments could be referred to a second element in other embodiments without departing from the teachings of the present invention. Exemplary embodiments of aspects of the present disclosure explained and illustrated herein include their complementary counterparts. The same reference numerals or the same reference designators denote the same elements throughout the specification.

Moreover, exemplary embodiments are described herein with reference to cross-sectional illustrations and/or plane illustrations that may be idealized exemplary illustrations. Accordingly, deviations from the shapes in the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures may be schematic in nature and their shapes may not illustrate the actual shape of a region of a device.

Devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

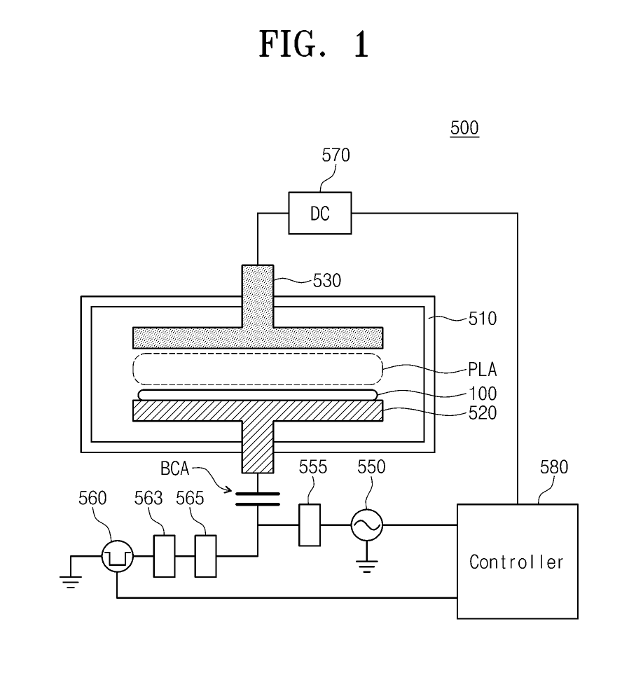

FIG. 1 is a schematic diagram illustrating a semiconductor fabricating apparatus according to some embodiments of the disclosure.

Referring to FIG. 1, a semiconductor fabricating apparatus 500 may include a process chamber 510 having an inner enclosed region in which a semiconductor fabrication process is performed. In addition, the semiconductor fabricating apparatus 500 may further include a lower electrode 520 disposed in the process chamber 510 and an upper electrode 530 disposed over the lower electrode 520 in the process chamber 510. The lower electrode 520 may have a top surface on which a substrate 100 (e.g., a wafer) is loaded, and the lower electrode may be electrically connected to a source external to the process chamber 510. In some embodiments, the lower electrode 520 may include an electrostatic chuck (ESC).

In some embodiments, the upper electrode 530 may have external connections and may be a shower head that is used to supply a process gas into the process chamber 510. In other words, the upper electrode 530 may act as both the shower head and the electrode used in the semiconductor fabrication process. In some other embodiments, the upper electrode 530 may be used as only the electrode, and the semiconductor fabricating apparatus 500 may include an additional gas supply pipe (not shown) or an additional supply nozzle (not shown).

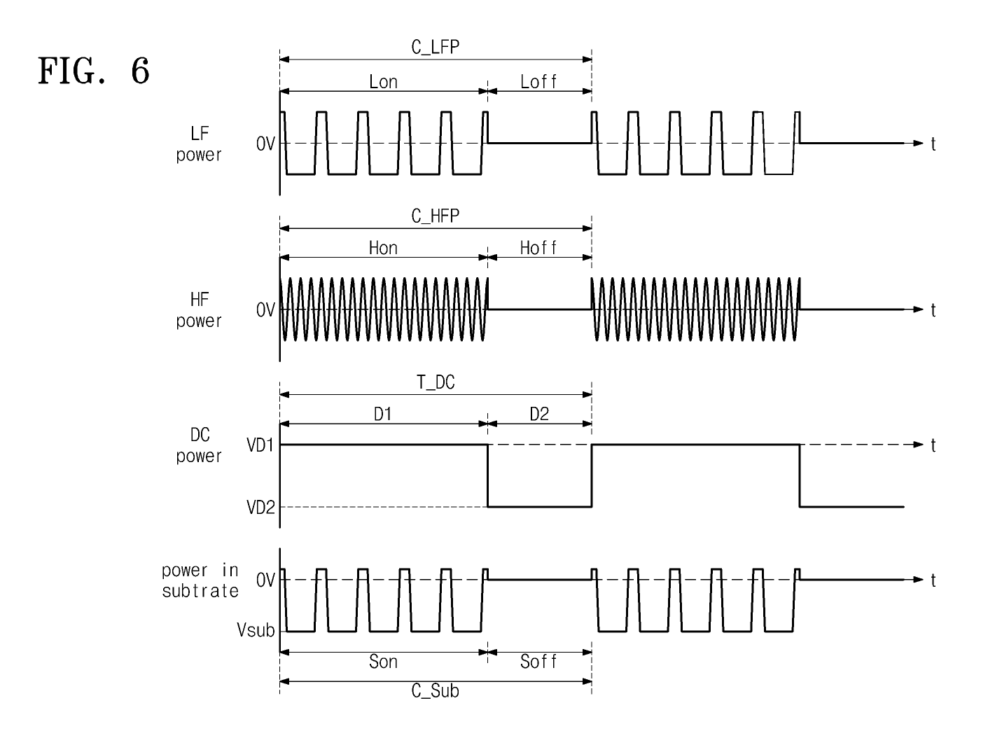

In some embodiments, a high-frequency power generator 550 may be connected to the lower electrode 520. The high-frequency power generator 550 may apply a high-frequency power to the lower electrode 520 during the semiconductor process. During the semiconductor process, plasma PLA may be generated from the process gas supplied into the process chamber 510 by the high-frequency power. The high-frequency power may be a radio-frequency (RF) power. The high-frequency power may have a sinusoidal waveform, as illustrated in FIG. 6. In some embodiments, a frequency of the high-frequency power used for generating the plasma PLA may be in a range of 13 MHz to 200 MHz, or in a range of 6 MHz to 300 MHz. For example, the frequency of the high-frequency power may be 13.56 MHz or 40.68 MHz. In some embodiments, the high-frequency power generator 550 may be connected to the upper electrode 530.

A low-frequency power generator 560 may be connected to the lower electrode 520. The low-frequency power generator 560 may apply a low-frequency power having a non-sinusoidal waveform (hereinafter, referred to as ‘a non-sinusoidal low-frequency power’) to the lower electrode 520 during the semiconductor process. The non-sinusoidal waveform means a waveform of which a shape is different from that of a sinusoidal waveform. A frequency of the non-sinusoidal low-frequency power is smaller than that of the high-frequency power. The non-sinusoidal low-frequency power may also be a RF power. In some embodiments, the frequency of the non-sinusoidal low-frequency power may be in a range of 100 Hz to 3.3 MHz. In particular, the frequency of the non-sinusoidal low-frequency power may be in a range of 100 Hz to 1 MHz.

The plasma PLA may be capacitively coupled plasma generated by the high-frequency power generator 550, so the semiconductor fabricating apparatus 500 may be a capacitively coupled plasma (CCP) apparatus. In some embodiments, the semiconductor fabricating apparatus 500 may be an etching apparatus. In other words, the semiconductor process may be an etching process. A blocking capacitor BCA may be connected between the low-frequency power generator 560 and the lower electrode 520 and between high-frequency power generator 550 and the lower electrode 520. The non-sinusoidal low-frequency power may be converted into a power necessary for the etching process in the loaded substrate 100 by the blocking capacitor BCA. This will be described in more detail later.

A high-frequency matching unit 555 may be connected between the blocking capacitor BCA and the high-frequency power generator 550. The high-frequency matching unit 555 may improve transmission efficiency of the high-frequency power.

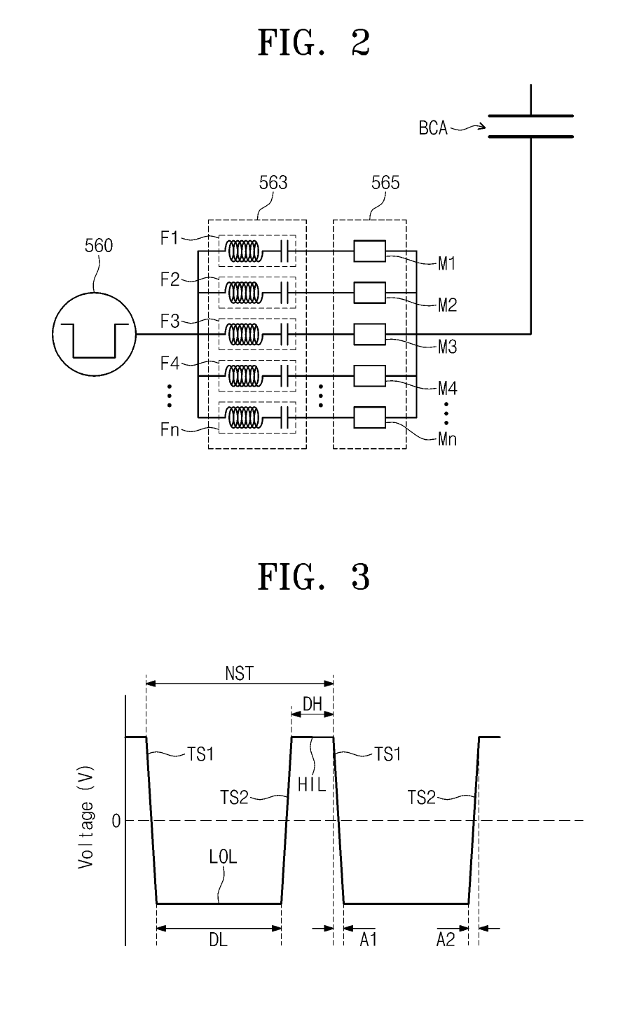

A low-frequency matching unit 565 may be connected between the blocking capacitor BCA and the low-frequency power generator 560, and a band-pass filtering unit 563 may be connected between the low-frequency matching unit 565 and the low-frequency power generator 560. The low-frequency matching unit 565 and the band-pass filtering unit 563 will be described later in more detail with reference to FIG. 2.

A direct current (DC) power generator 570 may be connected to the upper electrode 530. The DC power generator 570 may apply a DC power having a DC period to the upper electrode 530 during the semiconductor process (e.g., the etching process).

A controller 580 may be connected to the low-frequency power generator 560, the high-frequency power generator 550, and the DC power generator 570. The controller 580 may provide control signals to the power generators 550, 560, and 570, thereby controlling the power generators 550, 560, and 570.

In some embodiments, the non-sinusoidal low-frequency power may be formed by Fourier transformation. In some embodiments, a plurality of sinusoidal powers having different frequencies and different amplitudes from each other may be combined with each other to form the non-sinusoidal low-frequency power.

An embodiment of a waveform of the non-sinusoidal low-frequency power will be described in detail with reference to FIG. 3. FIG. 3 is a graph illustrating an embodiment of a waveform of a low-frequency power generated from the low-frequency power generator of FIG. 1.

Referring to FIG. 3, a period NST of the non-sinusoidal low-frequency power may have a first transition duration A1, a low-level duration DL, a second transition duration A2, and a high-level duration DH. The low-level duration DL is between the first transition duration A1 and the second transition duration A2, and the second transition duration A2 is between the low-level duration DL and the high-level duration DH. A level (i.e., a voltage level) of the non-sinusoidal low-frequency power may be transitioned from a high level to a low level during the first transition duration A1 and may be transitioned from the low level to the high level during the second transition duration A2. A reference designator TS1 indicates a variation of the voltage level of the non-sinusoidal low-frequency power during the first transition duration A1, and a reference designator TS2 indicates a variation of the voltage level of the non-sinusoidal low-frequency power during the second transition duration A2. For example, the variation TS1 may be a ramp down and variation TS2 may be a ramp up of the voltage level. The non-sinusoidal low-frequency power may apply a linear low-level voltage LOL during the low-level duration DL and may apply a linear high-level voltage HIL during the high-level duration DH. For example, the linear low-level voltage LOL may be a negative voltage, and the linear high-level voltage HIL may be a positive voltage.

Since the linear low-level voltage LOL is applied during the etching process, the amount of high-energy ions may be remarkably increased. As a result, openings with high aspect ratios may be uniformly and reliably formed. In addition, a processing time of the etching process may be reduced.

In some embodiments, a time length of the low-level duration DL may be different from a time length of the high-level duration DH. In some embodiments, as illustrated in FIG. 3, the time length of the low-level duration DL may be longer than the time length of the high-level duration DH. For example, the low-level duration DL may be greater than 1.5 times, greater than two times, and in some examples, greater than five times the high-level duration DH. Alternatively, the time length of the high-level duration DH may be longer than the time length of the low-level duration DL.

In the present embodiment, the low-level voltage LOL may be constant during the low-level duration DL, and the high-level voltage HIL may be constant during the high-level duration DH.

Next, the band-pass filtering unit 563 and the low-frequency matching unit 565 will be described in detail with reference to FIG. 2. FIG. 2 is a schematic diagram illustrating the low-frequency power generator 560, a band-pass filtering unit 563, and a low-frequency matching unit 565 of FIG. 1.

Referring to FIGS. 1 and 2, the band-pass filtering unit 563 may include a plurality of band-pass filters F1, F2, F3, F4, . . . , and Fn of which each includes a coil and a capacitor. The capacitors of the band-pass filters F1, F2, F3, F4, . . . , and Fn may have capacitance values different from each other. The band-pass filtering unit 563 may decompose the non-sinusoidal low-frequency power into a plurality of sinusoidal components, and the sinusoidal components may be outputted through the band-pass filters F1, F2, F3, F4, . . . , and Fn, respectively. In some embodiments, a fast Fourier transform circuit (not shown) may be connected between the low-frequency power generator 560 and the band-pass filtering unit 563.

The low-frequency matching unit 565 may include a plurality of matching circuits M1, M2, M3, M4, . . . , and Mn that are connected to the band-pass filters F1, F2, F3, F4, . . . , and Fn, respectively. The sinusoidal components respectively outputted from the band-pass filters F1, F2, F3, F4, . . . , and Fn may pass through the matching circuits M1, M2, M3, M4, . . . , and Mn and may be then combined with each other to form the non-sinusoidal low-frequency power. Each of the matching circuits M1, M2, M3, M4, . . . , and Mn may comprise circuits (e.g., with capacitors, inductors and/or resistors) that provide an impedance matching of the sinusoidal voltage/power transmitted from the corresponding band-pass filter F1, F2, F3, F4, . . . , and Fn to which it is connected. Thus, the low-frequency matching unit 565 may improve the transmission efficiency of the non-sinusoidal low-frequency power. In other words, a loss of the non-sinusoidal low-frequency power may be reduced or minimized by the method described above. The non-sinusoidal low-frequency power outputted from the low-frequency matching unit 565 may be applied to the lower electrode 520 through the blocking capacitor BCA.

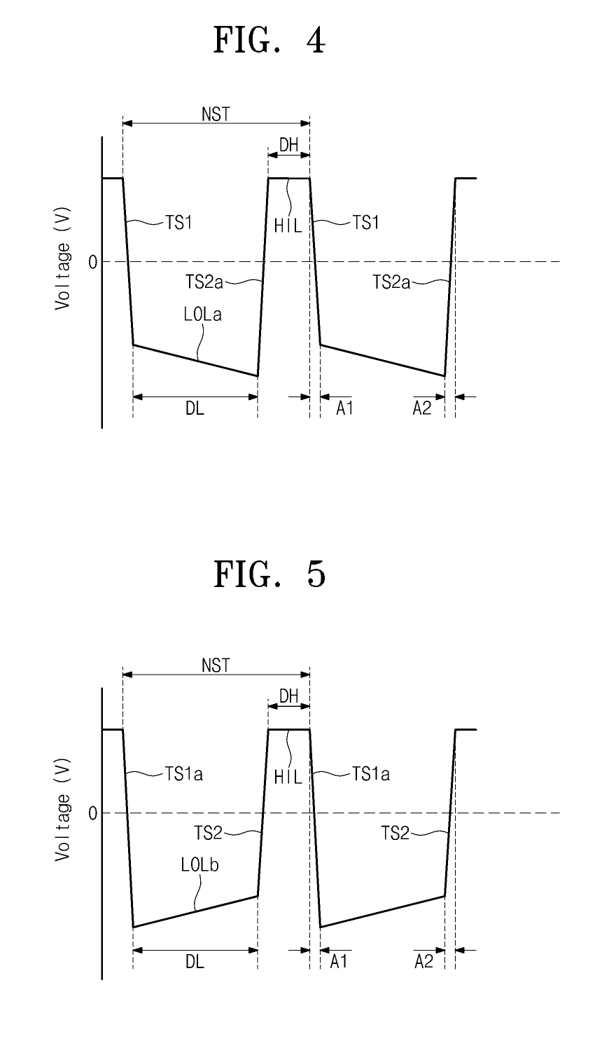

In some embodiments, the waveform of the non-sinusoidal low-frequency power may have shapes different from that of the waveform of FIG. 3. This will be described with reference to FIGS. 4 and 5. FIG. 4 is a graph illustrating another embodiment of a waveform of a low-frequency power generated from the low-frequency power generator of FIG. 1. FIG. 5 is a graph illustrating still another embodiment of a waveform of a low-frequency power generated from the low-frequency power generator of FIG. 1.

As illustrated in FIGS. 4 and 5, a low-level voltage LOLa or LOLb may be gradually or linearly varied during the low-level duration DL.

In the embodiment of FIG. 4, the low-level voltage LOLa may be gradually lowered during the low-level duration DL. For example, the low-level voltage LOLa may be linearly lowered during the low-level duration DL. Thus, a voltage difference TS2a of the non-sinusoidal low-frequency power in the second transition duration A2 may be greater than a voltage difference TS1 of the non-sinusoidal low-frequency power in the first transition duration A1. The loaded substrate 100 may be gradually charged during the semiconductor process. A voltage applied in the substrate 100 may gradually drop by a gradual positive charging phenomenon. The charge buildup phenomenon deteriorates uniformity of the semiconductor process. However, the low-level voltage LOLa according to the present embodiment may be gradually lowered during the low-level duration DL to compensate the gradual voltage drop caused by the gradual charging phenomenon. In other words, it is possible to minimize or prevent deterioration of the uniformity of the semiconductor fabrication process.

In the embodiment of FIG. 5, the low-level voltage LOLb may gradually rise during the low-level duration DL. In other words, the low-level voltage LOLa may linearly rise during the low-level duration DL. Thus, a voltage difference TS1a of the non-sinusoidal low-frequency power in the first transition duration A1 may be greater than a voltage difference TS2 of the non-sinusoidal low-frequency power in the second transition duration A2.

Next, a method of operating the semiconductor fabricating apparatus 500 illustrated in FIGS. 1 and 2 will be described with reference to FIG. 6. Hereinafter, the non-sinusoidal low-frequency power having the waveform of FIG. 3 will be described as an example for the purpose of ease and convenience in explanation.

FIG. 6 is a graph illustrating exemplary powers generated from power generators of FIG. 1 and a power generated in a substrate by the powers of the power generators to explain a method of operating the semiconductor fabricating apparatus of FIG. 1.

Referring to FIGS. 1 to 3 and 6, a direct current (DC) period T_DC of the DC power may have a first level duration D1 and a second level duration D2. The DC power may apply a first direct current (DC) voltage VD1 to the upper electrode 530 during the first level duration D1 and may apply a second direct current (DC) voltage VD2 to the upper electrode 530 during the second level duration D2. The second DC voltage VD2 is different from the first DC voltage VD1. In some embodiments, the first DC voltage VD1 may be 0 V, and the second DC voltage VD2 may be a negative voltage.

The non-sinusoidal low-frequency power may have a low-frequency cycle C_LFP having a low-frequency on-duration Lon and a low-frequency off-duration Loff. The non-sinusoidal low-frequency power may be turned-on during the low-frequency on-duration Lon and may be turned-off during the low-frequency off-duration Loff. Likewise, the high-frequency power may have a high-frequency cycle C_HFP having a high-frequency on-duration Hon and a high-frequency off-duration Hoff. The high-frequency power may be turned-on during the high-frequency on-duration Hon and may be turned-off during the high-frequency off-duration Hoff. In other words, during the semiconductor process, the non-sinusoidal low-frequency power may be applied to the lower electrode 520 in the low-frequency cycle C_LFP and the high-frequency power may be applied to the lower electrode 520 in the high-frequency cycle C_HFP.

In some embodiments, the low-frequency cycle C_LFP, the high-frequency cycle C_HFP, and the DC period T_DC may be synchronized with each other during the semiconductor process. In other words, a turning-on time and a turning-off time of the cycles C_LFP, C_HFP, and the DC period T_DC may be the same for each. A time length of the first level duration D1 of the DC period T_DC may also be equal to those of the low-frequency and high-frequency on-durations Lon and Hon of the low-frequency and high-frequency cycles C_LFP and C_HFP, and a time length of the second level duration D2 of the DC period T_DC may also be equal to those of the low-frequency and high-frequency off-durations Loff and Hoff of the low-frequency and high-frequency cycles C_LFP and C_HFP. The non-sinusoidal low-frequency power and the high-frequency power may be turned-on during the first level duration D1 of the DC period T_DC and may be turned-off during the second level duration D2 of the DC period T_DC. In some embodiments, as illustrated in FIG. 6, the cycles C_LFP and C_HFP and the DC period T_DC may also be repeated at the same time. The controller 580 may control the power generators 550, 560, and 570 to control operations of the low-frequency, high-frequency, and DC powers.

A power generated in the substrate 100 loaded on the lower electrode 520 may have a non-sinusoidal waveform due to the non-sinusoidal low-frequency power. Where the non-sinusoidal low-frequency power is applied to the lower electrode 520 through the blocking capacitor BCA, an absolute value of a low-level voltage Vsub of the power in the substrate 100 may be greater than an absolute value of a high-level voltage of the power in the substrate 100, as illustrated in FIG. 6. The power in the substrate 100 may have a substrate cycle C_sub having an on-duration Son and an off-duration Soff. A time length of the on-duration Son may be substantially equal to those of the low-frequency on-duration Lon, the high-frequency on-duration Hon, and the first level duration D1. A time length of the off-duration Soff may be substantially equal to those of the low-frequency off-duration Loff, the high-frequency off-duration Hoff, and the second level duration D2. Due to the non-sinusoidal low-frequency power, the low-level voltage Vsub of the power in the substrate 100 may be linearly applied. Thus, the amount of the high-energy ions may be increased to improve an etch rate.

In some embodiments, the time length of the first level duration D1 may be different from the time length of the second level duration D2. For example, the time length of the first level duration D1 may be longer than the time length of the second level duration D2. In some embodiments, the time length of the second level duration D2 may be longer than the time length of the first level duration D1. In some embodiments, the time lengths of the low-frequency and high-frequency on-durations Lon and Hon are equal to that of the first level duration D1, and the time lengths of the low-frequency and high-frequency off-durations Loff and Hoff are equal to that of the second level duration D2. In some embodiments, the time lengths of the low-frequency and high-frequency on-durations Lon and Hon may be different from those of the low-frequency and high-frequency off-durations Loff and Hoff, respectively. In other words, the time lengths of the low-frequency and high-frequency on-durations Lon and Hon may be longer or shorter than those of the low-frequency and high-frequency off-durations Loff and Hoff, respectively.

As described above, during the second level duration D2, the second DC voltage VD2 is applied and the low-frequency and high-frequency powers are turned-off. The second DC voltage VD2 applied to the upper electrode 530 may be a negative voltage. Positive ions of the plasma PLA may collide with the upper electrode 530 by virtue of the application of the second DC voltage VD2 (a negative voltage) to the upper electrode 530, and thus, secondary electrons may be generated and emitted from the upper electrode 530. The secondary electrons may be supplied to the loaded substrate 100 by virtue of being repelled by application of the second DC voltage VD2 (a negative voltage) to the upper electrode 530 and/or the positively charged substrate 100. As a result, the substrate 100 positively charged during the first level duration D1 (e.g., during the low-frequency and high-frequency on-durations Lon and Hon) may be neutralized by the secondary electrons.

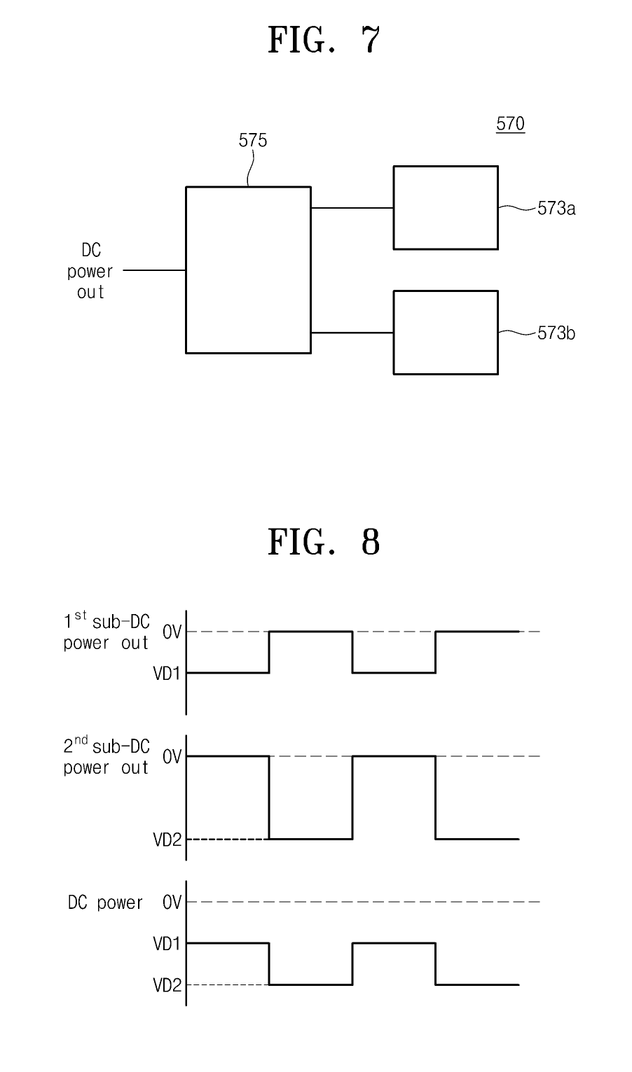

In some embodiments, the first DC voltage VD1 may be 0 V, and the second DC voltage VD2 may be a negative voltage. In other embodiments, all of the first and second voltages VD1 and VD2 may be negative voltages and the second DC voltage VD2 may be lower than the first DC voltage VD1. The DC power generator 570 will be described in detail with reference to FIGS. 7 and 8.

FIG. 7 is a schematic block diagram illustrating a direct current (DC) power generator of FIG. 1. FIG. 8 is a graph illustrating a method of operating the DC power generator of FIG. 7.

Referring to FIG. 7, the DC power generator 570 may include a first generator 573a generating a first sub-DC power, a second generator 573b generating a second sub-DC power, and a DC pulse unit 575 that combines the first and second sub-DC powers to provide a new DC power output.

Referring to FIGS. 7 and 8, a period of the first sub-DC power of the first generator 573a may have a first on-duration and a first off-duration, and a period of the second sub-DC power of the second generator 573b may have a second off-duration and a second on-duration. The first sub-DC power may provide the first DC voltage VD1 during the first on-duration and may provide 0 V during the first off-duration. The second sub-DC power may provide 0 V during the second off-duration and may provide the second DC voltage VD2 during the second on-duration. The first on-duration may fully overlap the second off-duration, and the first off-duration may fully overlap the second on-duration. For example, the first on-duration may begin when the second off-duration begins, and the first on-duration may transition to the first off-duration when the second off-duration transitions to the second on-duration. Also, the first on-duration may equal the second off-duration just as the first off-duration may equal the second on-duration.

The DC pulse unit 575 combines the first and second sub-DC powers to generate the DC power. In other words, as described with reference to FIG. 6, the period of the DC power may have the first level duration during which the first DC voltage VD1 is applied, and the second level duration during which the second DC voltage VD2 is applied.

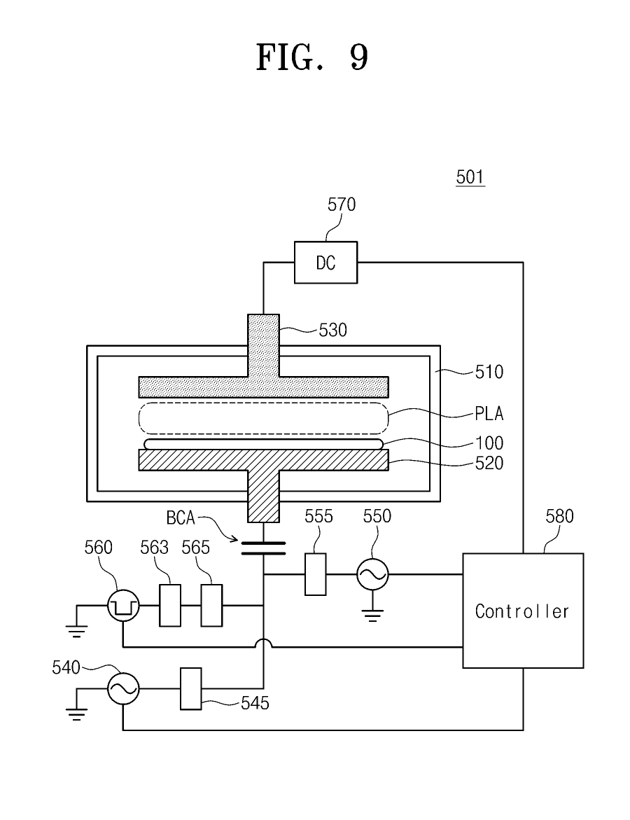

FIG. 9 is a schematic diagram illustrating a semiconductor fabricating apparatus according to another embodiment of the disclosure. The same elements as described in the embodiment of FIG. 1 will be indicated by the same reference numerals or the same reference designators. For the purpose of ease and convenience in explanation, descriptions of the same elements as in the embodiment of FIG. 1 will be omitted or mentioned briefly. In other words, differences between the present embodiment and the embodiment of FIG. 1 will be mainly described hereinafter.

Referring to FIG. 9, a semiconductor fabricating apparatus 501 according to the present embodiment may include a first low-frequency power generator 540 and a second low-frequency power generator 560. The first low-frequency power generator 540 may generate a first low-frequency power having a sinusoidal waveform, and the second low-frequency power generator 560 may generate a second low-frequency power having a non-sinusoidal waveform. The first low-frequency power may be used in a first semiconductor process, and the second low-frequency power may be used in a second semiconductor process. In some embodiments, the first semiconductor process and the second semiconductor process may be a first etching process and a second etching process, respectively. Hereinafter, the first and second etching processes will be described together for the purpose of ease and convenience in explanation, but they may be entirely distinct and independent from each other in operation.

The first and second low-frequency power generators 540 and 560 may be connected to the lower electrode 520. The blocking capacitor BCA may be connected between the lower electrode 520 and the first low-frequency power generator 540 and between the lower electrode 520 and the second low-frequency power generator 560. A first low-frequency matching unit 545 may be connected between the blocking capacitor BCA and the first low-frequency power generator 540. The first low-frequency matching unit 545 may improve transmission efficiency of the first low-frequency power having the sinusoidal waveform. The first low-frequency power generator 540 may be connected to the controller 580, and the controller 580 may control operations of the first low-frequency power generator 540. The first low-frequency power having the sinusoidal waveform may have a frequency ranging from 50 Hz to 5 MHz. For example, the frequency of the sinusoidal low-frequency power may be in a range of 100 Hz to 3.3 MHz.

A second low-frequency matching unit 565 may be connected to the blocking capacitor BCA and the second low-frequency power generator 560, and the band-pass filtering unit 563 may be connected between the second low-frequency matching unit 565 and the second low-frequency power generator 560. The second low-frequency power generator 560, the band-pass filtering unit 563, and the second low-frequency matching unit 565 may be the same as described with reference to FIGS. 1 and 2.

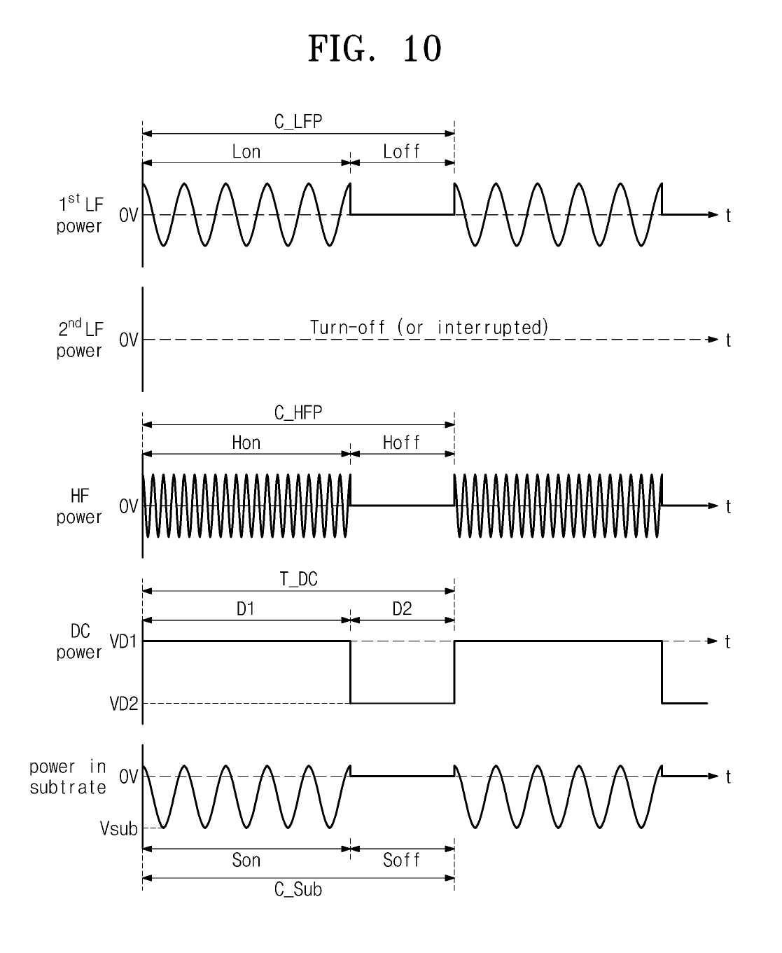

As described above, the first low-frequency power may have the sinusoidal waveform (see FIG. 10). Thus, low-energy ions may be mainly supplied to the substrate 100 loaded on the lower electrode 520 during the first etching process. The low-energy ions may generate etch-by-products such as a polymer. Thus, a profile of an etched region may be controlled and/or a mask used in the first etching process may be protected by the etch-by-products.

The semiconductor fabricating apparatus 501 described above may include the first low-frequency power generator 540 and the second low-frequency power generator 560 to perform the first etching process capable of controlling the etch-by-products and the second etching process capable of improving the etch rate, respectively. Thus, the semiconductor fabricating apparatus 501 may etch various types of openings that satisfy various, desired characteristics.

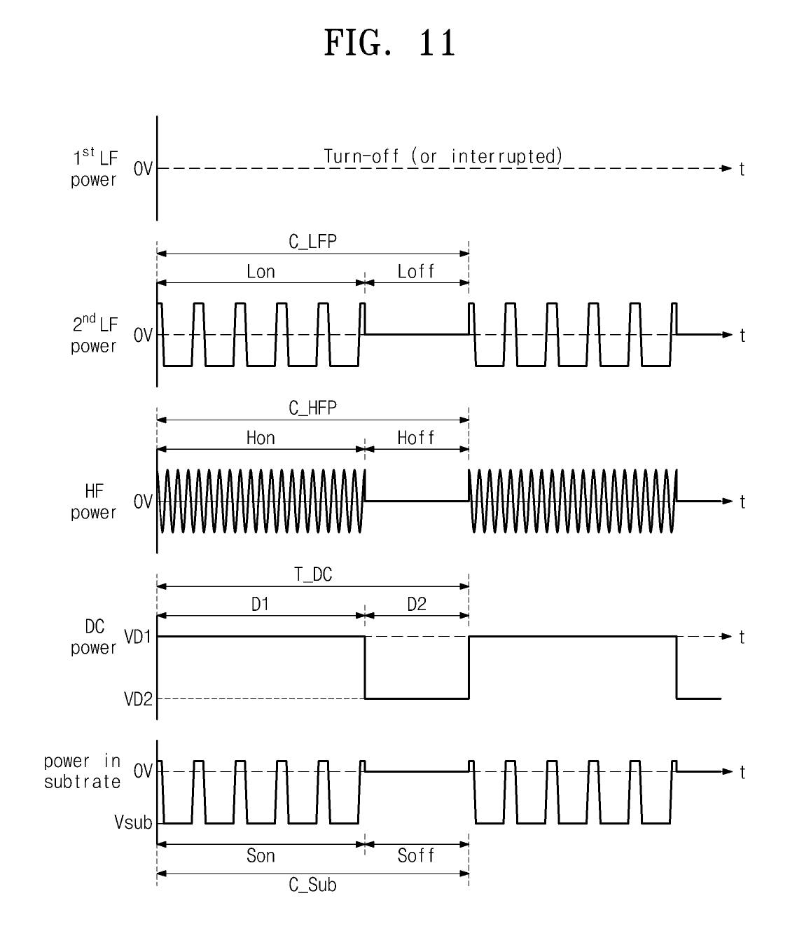

Next, a method of operating the semiconductor fabricating apparatus 501 will be described in detail with reference to FIGS. 10 and 11.

FIGS. 10 and 11 are graphs illustrating powers generated from power generators of FIG. 9 and a power generated in a substrate by the power generators to explain a method of operating the semiconductor fabricating apparatus of FIG. 9.

Referring to FIGS. 9 and 10, during the first etching process, the first low-frequency power generator 540 may provide the first low-frequency power to the lower electrode 520 in a low-frequency cycle C_LFP having a low-frequency on-duration Lon and a low-frequency off-duration Loff. The first low-frequency power having the sinusoidal waveform may be turned-on during the low-frequency on-duration Lon and may be turned-off during the low-frequency off-duration Loff. During the low-frequency cycle C_LFP, the controller 580 may interrupt the second low-frequency power of the second low-frequency power generator 560. In other words, the second low-frequency power having the non-sinusoidal waveform may be interrupted or turned-off during the first etching process.

During the first etching process, the high-frequency power generator 550 may provide the high-frequency power to the lower electrode 520 in the high-frequency cycle C_HFP and the DC power generator 570 may apply the DC power of the DC period T_DC to the upper electrode 530. Throughout the first etching process, the low-frequency cycle C_LFP, the high-frequency C_HFP, and the DC period T_DC may be synchronized with each other. For example, a turning-on time and a turning-off time of the cycles C_LFP, C_HFP, and the DC period T_DC may be the same for each. In still other words, during the first level duration D1 of the DC period T_DC, the first low-frequency power and the high-frequency power may be turned-on and the first DC voltage VD1 may be applied. During the second level duration D2 of the DC period T_DC, the first low-frequency power and the high-frequency power may be turned-off and the second DC voltage VD2 may be applied.

Since the first low-frequency power having the sinusoidal waveform is provided, a power in the loaded substrate 100 may have a sinusoidal waveform, as illustrated in FIG. 10. The duration of the sinusoidal waveform in the loaded substrate 100 having the maximum positive voltage value is shorter than that of the duration of the non-sinusoidal waveform in the loaded substrate 100 having the maximum positive voltage value, as illustrated in FIGS. 10 and 11. Thus, a relatively large amount of low-energy ions may be provided to the substrate 100 during the first etching process. In other words, the amount of the etch-by-products may be increased to control the profile of the etched region and/or to protect the mask.

Referring to FIGS. 9 and 11, the controller 580 may operate the second low-frequency power generator 560, the high-frequency power generator 550, and the DC power generator 570 during the second etching process. The controller 580 may interrupt the first low-frequency power of the first low-frequency power generator 540 by initiating the second etching process. In other words, the first low-frequency power may be interrupted or turned-off during the second etching process. The second etching process may be the same as described with reference to FIGS. 1 and 6. In some embodiments, the second etching process may be performed after the first etching process is performed. In other embodiments, the first etching process may be performed after the second etching process is performed.

In embodiments of the operating method described above, the second low-frequency power having the non-sinusoidal waveform may be interrupted during the first etching process, and the first low-frequency power having the sinusoidal waveform may be interrupted by initiation of the second etching process. For example, the first etching process may be immediately followed by the second etching process of the same substrate in situ in the same process chamber without a vacuum seal break of the process chamber. In another embodiment, the semiconductor fabricating apparatus 501 may provide the first and second low-frequency powers at the same time during an etching process.

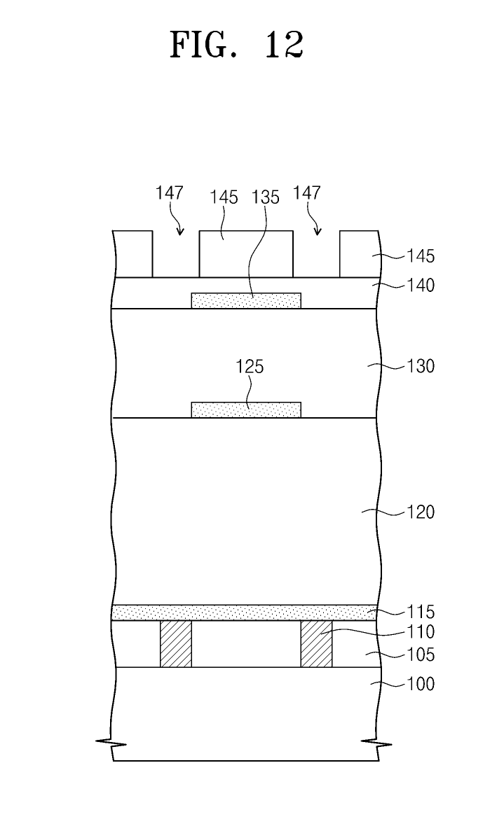

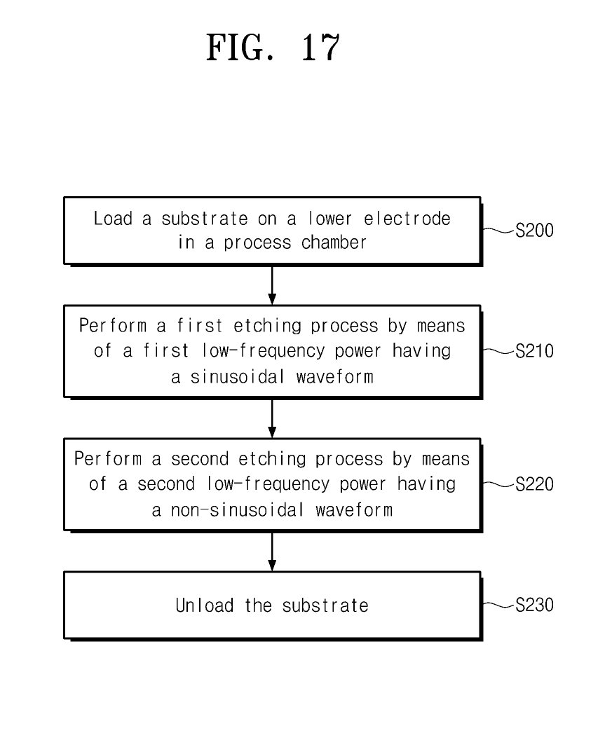

FIGS. 12 to 16 are cross-sectional views illustrating a method of fabricating a semiconductor device according to some embodiments of the disclosure. FIG. 17 is a flowchart illustrating a method of performing a semiconductor fabrication process using the semiconductor fabricating apparatus of FIG. 9 and according to embodiments of the disclosure.

Referring to FIG. 12, an interlayer insulating layer 105 may be formed on a substrate 100, and contact plugs 110 may be formed to penetrate the interlayer insulating layer 105. An etch stop layer 115 and a first mold layer 120 may be sequentially formed on the interlayer insulating layer 105 and the contact plugs 110. The etch stop layer 115 may be formed of an insulating material having an etch selectivity with respect to the first mold layer 120. For example, the etch stop layer 115 may be formed of a silicon nitride layer, and the first mold layer 120 may be formed of a silicon oxide layer.

A first support pattern 125 may be formed on the first mold layer 120. The first support pattern 125 may be formed of an insulating material having an etch selectivity with respect to the first mold layer 120. For example, the first support pattern 125 may be formed of silicon nitride. A second mold layer 130 may be formed on the first support pattern 125 and the first mold layer 120. The second mold layer 130 may be formed of the same material as the first mold layer 120. For example, the second mold layer 130 may be formed of a silicon oxide layer.

A second support pattern 135 may be formed on the second mold layer 130. Except for the intervening second mold layer 130, the second support pattern 135 may be overlapped with and thus may be positioned directly above the first support pattern 125. The second support pattern 135 may be formed of an insulating material having an etch selectivity with respect to the second mold layer 130. For example, the second support pattern 135 may be formed of silicon nitride. A third mold layer 140 may be formed on the second support pattern 135 and the second mold layer 130. The third mold layer 140 may be formed of the same material as the second mold layer 130. For example, the third mold layer 140 may be formed of a silicon oxide layer.

The first to third mold layers 120, 130, and 140 may correspond to an etch target layer. A mask layer 145 having mask openings 147 may be formed on the third mold layer 140. The mask layer 145 may include at least one of a hard mask layer (e.g., an amorphous carbon layer or a poly-silicon layer) and a photoresist layer.

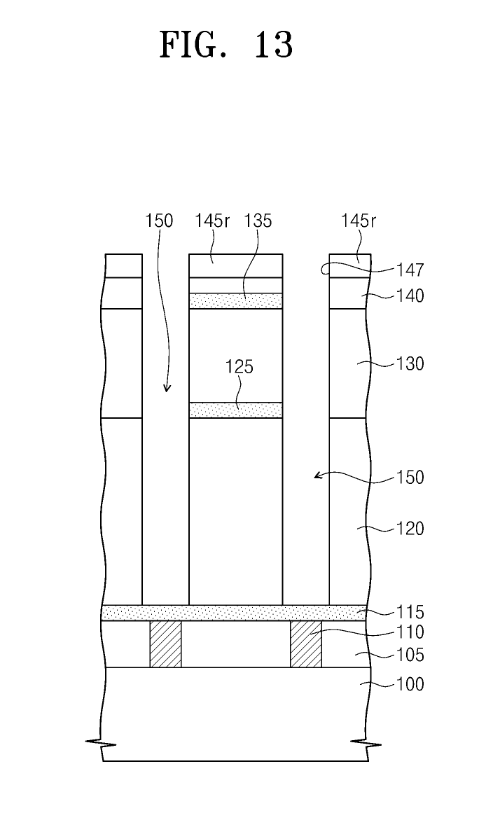

Referring to FIG. 13, the third, second, and first mold layers 140, 130, and 120 may be etched using the mask layer 145 as an etch mask to form openings 150. The openings 150 may have hole-shapes. Each of the openings 150 may expose a portion of the etch stop layer 115 disposed on each of the contact plugs 110. In addition, each of the openings 150 may expose portions of sidewalls of the first and second support patterns 125 and 135.

According to some embodiments, the mold layers 140, 130, and 120 may be etched using the semiconductor fabricating apparatus 500 of FIG. 1. Referring to FIGS. 13, 1, and 6, the substrate 100 including the mold layers 140, 130, and 120 and the mask layer 145 may be loaded on the lower electrode 520 in the process chamber 510. A process gas (e.g., an etching gas) may be supplied into the process chamber 510. In some embodiments, if the etch target layer includes silicon oxide and/or silicon nitride, the etching gas may include at least one of oxygen (O₂), fluorocarbon (e.g., C₄F₈ and/or C₄F₆), hydro-fluorocarbon (e.g., CHF₃, CH₂F₂, and/or CH₃F), and NF₃. The etching gas may further include an argon (Ar) gas used as a carrier gas.

The low-frequency and high-frequency powers generated from the power generators 560 and 550, respectively, may be provided to the lower electrode 520, and the DC power generated from the power generator 570 may be provided to the upper electrode 530, as described with reference to FIGS. 1 and 6. According to example embodiments, the openings 150 may be formed.

According to other embodiments, the mold layers 140, 130, and 120 may be etched using the semiconductor fabricating apparatus 501 of FIG. 9. This will be described with reference to FIG. 17.

Referring to FIGS. 13, 9, 10, 11, and 17, the substrate 100 may be loaded on the upper electrode 520 in the process chamber 510 of the semiconductor fabricating apparatus 501 (S200).

A process gas may be provided into the process chamber 510, and a first etching process may be performed using the first low-frequency power having the sinusoidal waveform on the substrate 100 (S210). The first etching process may be performed as described with reference to FIGS. 9 and 10. The second low-frequency power having the non-sinusoidal waveform may be interrupted during the first etching process. A portion of the mold layers 140, 130, and 120 under the mask opening 147 may be etched during the first etching process.

A second etching process may be performed using the second low-frequency power having the non-sinusoidal waveform on the substrate 100 (S220). The second etching process may be performed as described with reference to FIGS. 9 and 11. The first low-frequency power of the sinusoidal waveform may be interrupted during the second etching process. A portion of the mold layers 140, 130, and 120 under the mask opening 147 may be etched during the second etching process.

The first etching process S210 and the second etching process S220 may be performed in-situ in the process chamber 510. The opening 150 may be formed in the mold layers 140, 130, and 120 by the first and second etching processes S210 and S220. As described above, the first etching process S210 using the first low-frequency power of the sinusoidal waveform may control the etch-by-products (e.g., the polymer), so a profile of the opening 150 may be controlled and the mask layer 145 may be protected when the mold layers 140, 130, and 120 are etched. The second etching process S220 using the second low-frequency power of the non-sinusoidal waveform may improve an etch rate, so uniformity of depths of the openings 150 may be improved and a formation time of the openings 150 may be reduced. As a result, the first and second etching processes S210 and S220 having different characteristics from each other may be performed to form the openings 150. In other words, reliability and reproducibility of the semiconductor device may be improved.

The second etching process S220 may be performed after the first etching process S210 is performed. Alternatively, the first etching process S210 may be performed after the second etching process S220 is performed. According to other embodiments of the disclosure, the first etching process S210 and the second etching process may be alternately and repeatedly performed to form the openings 150. It will be understood that a variety of different openings in number, diameter, and relative positioning may be formed by the disclosed operational methods.

After the formation of the openings 150, the substrate 100 may be unloaded from the process chamber 510 (S230).

A portion 145r of the mask layer may remain on the third mold layer 140 after the formation of the openings 150.

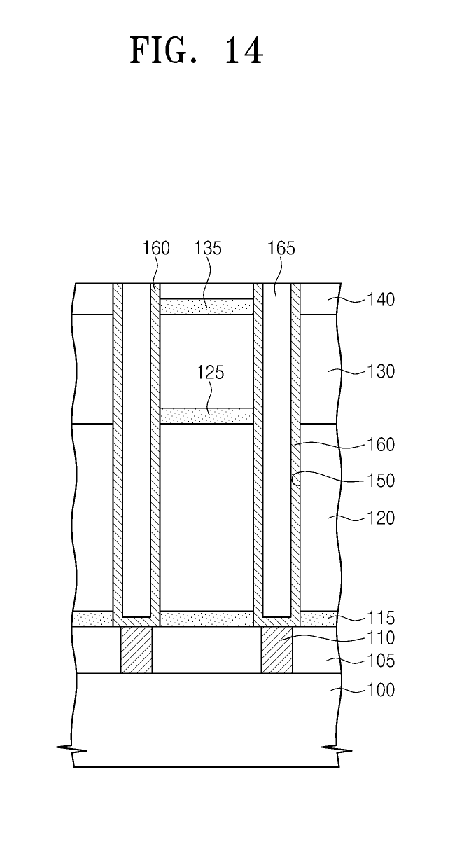

Referring to FIG. 14, in some embodiments the remaining mask layer 145r may be removed. Portions of the etch stop layer 110 under the openings 150 may also be removed to expose the contact plugs 110.

A conductive layer may be conformally formed on the substrate 100 having the openings 150 exposing the contact plugs 110, and a filling layer may be formed on the conductive layer to fill the openings 150. Next, the filling layer and the conductive layer may be planarized to form a node electrode 160 and a filling pattern 165 in each of the openings 150. The filling pattern 165 may be formed of the same material as the mold layers 120, 130, and 140. For example, the filling pattern 165 may be formed of silicon oxide. The node electrode 160 may include at least one of a doped semiconductor material (e.g., doped silicon), a conductive metal nitride (e.g., titanium nitride or tantalum nitride), a metal (e.g., tungsten, titanium, tantalum, or a noble metal), or a conductive metal oxide (e.g., iridium oxide).

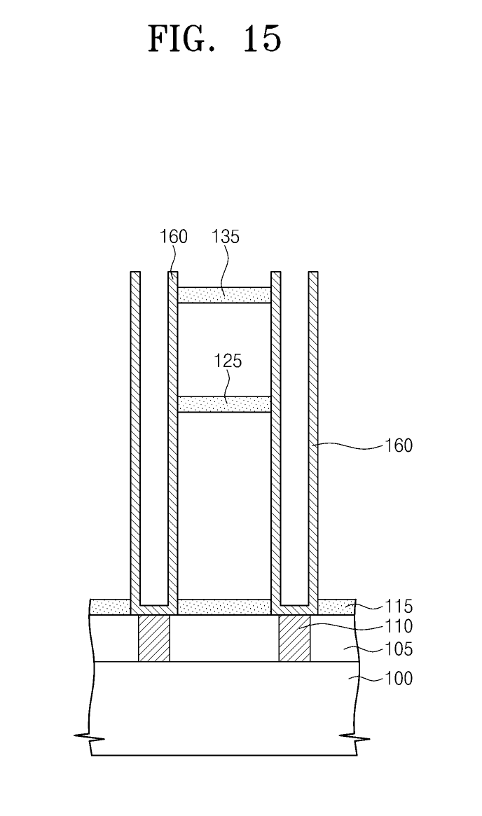

Referring to FIG. 15, the mold layers 140, 130, and 120 and the filling patterns 165 may be removed to expose surfaces of the node electrodes 160. At this time, the first and second support patterns 125 and 135 may remain to be disposed between the node electrodes 160. The node electrodes 160 may be supported by the first and second patterns 125 and 135.

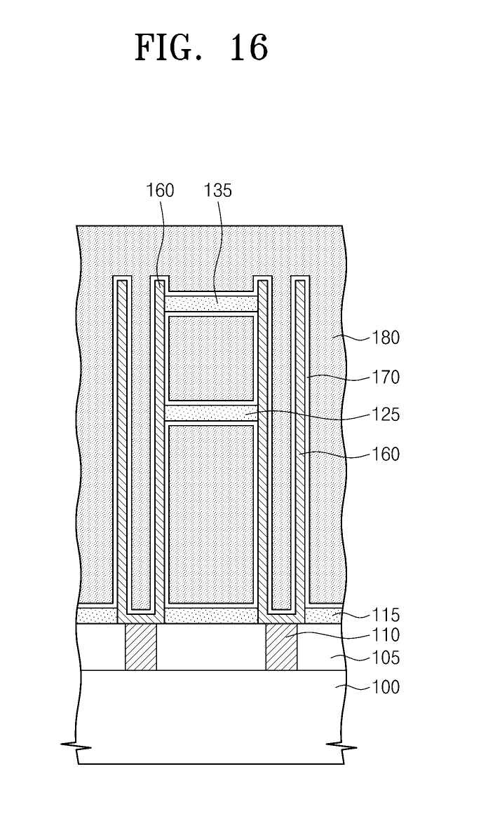

Referring to FIG. 16, a dielectric layer 170 may be conformally formed on the surfaces of the node electrodes 160. At this time, the dielectric layer 170 may also be formed on exposed surfaces of the first and second support patterns 125 and 135. The dielectric layer 170 may include at least one of a silicon oxide layer, a silicon nitride layer, or a high-k dielectric layer (e.g., an insulating metal oxide layer such as a titanium oxide layer, a tantalum oxide layer, a hafnium oxide layer, and/or an aluminum oxide layer). A plate electrode 180 may be formed on the dielectric layer 170 to cover the surfaces of the node electrodes 160. The plate electrode 180 may include at least one of a doped semiconductor material (e.g., doped silicon), a conductive metal nitride (e.g., titanium nitride or tantalum nitride), a metal (e.g., tungsten, titanium, tantalum, or a noble metal), or a conductive metal oxide (e.g., iridium oxide). The node electrode 160, the dielectric layer 170, and the plate electrode 180 may constitute a capacitor. The capacitor is an example semiconductor device that may be fabricated in an example embodiment of the disclosed method, and it may be included in a unit cell of a dynamic random access memory (DRAM) device.

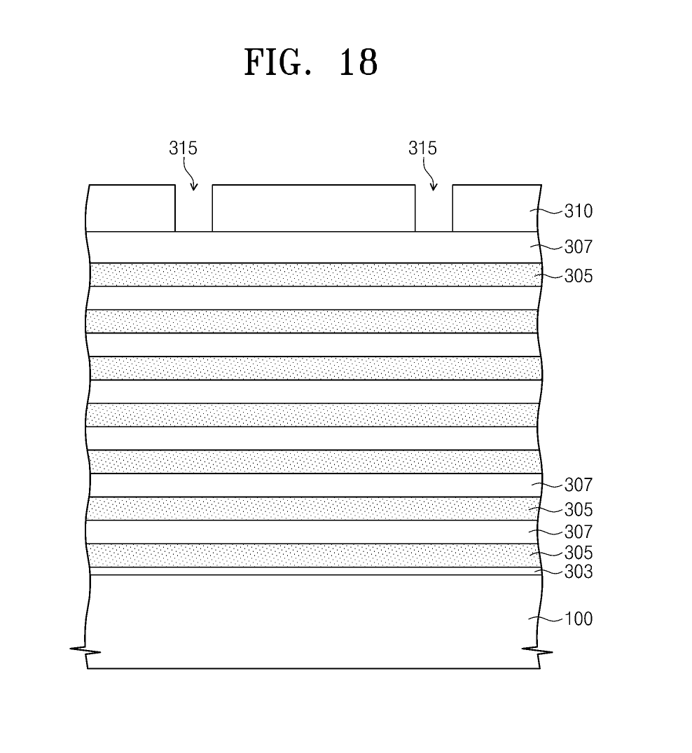

FIGS. 18 to 24 are cross-sectional views illustrating a method of fabricating a semiconductor device according to other embodiments of the disclosure.

Referring to FIG. 18, sacrificial layers 305 and insulating layers 307 may be alternately and repeatedly formed on a substrate 100. The sacrificial layers 305 may be formed of a material having an etch selectivity with respect to the insulating layers 307. For example, the insulating layers 307 may be formed of silicon oxide layers, and the sacrificial layers 305 may be formed of silicon nitride layers. A buffer insulating layer 303 may be formed on the substrate 100 before the formation of the sacrificial layers 305 and the insulating layers 307. The buffer insulating layer 303 may be formed of a silicon oxide layer. The buffer insulating layer 303, the sacrificial layers 305, and the insulating layers 307 may be included in an etch target layer.

A mask layer 310 may be formed on an uppermost insulating layer 307. The mask layer 310 may be patterned to form mask openings 315. The mask layer 310 may include at least one of a hard mask layer (e.g., an amorphous carbon layer or a poly-silicon layer) and a photoresist layer.

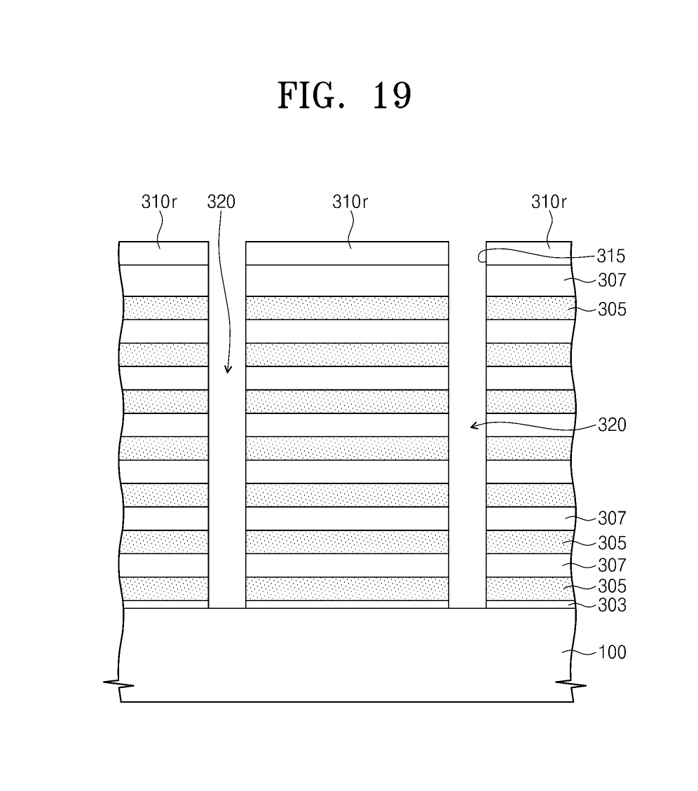

Referring to FIG. 19, the etch target layer (e.g., the insulating layers 307, the sacrificial layers 305, and the buffer insulating layer 303) may be etched using the mask layer 310 as an etch mask to form vertical holes 320. The vertical holes 320 may expose the substrate 100.

In example embodiments, the vertical holes 320 may be formed using the semiconductor fabricating apparatus 500 of FIG. 1. In other words, the substrate 100 having the layers 303, 305, and 307 and the mask layer 310 may, as depicted in FIG. 1, be loaded on the lower electrode 520 of the semiconductor fabricating apparatus 500, and an etching gas may be supplied into the process chamber 510. The etching gas may include at least one of oxygen (O₂), fluorocarbon (e.g., C₄F₈ and/or C₄F₆), hydro-fluorocarbon (e.g., CHF₃, CH₂F₂, and/or CH₃F), and NF₃. The etching gas may further include an argon (Ar) gas used as a carrier gas. The semiconductor fabricating apparatus 500 may be operated as described with reference to FIGS. 1 and 6, so the etching process may be performed to form the vertical holes 320.

In other example embodiments, the vertical holes 320 may be formed using the semiconductor fabricating apparatus 501 of FIG. 9. Referring to FIGS. 19, 9, 10, 11, and 17, the substrate 100 having the layers 303, 305, and 307 and the mask layer 310 may be loaded on the lower electrode 520 of the semiconductor fabricating apparatus 501 (S200), and the etching gas may be supplied into the process chamber 510. A first etching process using the first low-frequency power, the sinusoidal waveform, may be performed on the substrate 100 (S210). A second etching process using the second low-frequency power of the non-sinusoidal waveform may be performed on the substrate 100 (S220). The first etching process may be performed as described with reference to FIGS. 9 and 10, and the second etching process may be performed as described with reference to FIGS. 9 and 11.

After one of the first and second etching processes S210 and S220 is performed, the other of the first and second etching processes S210 and S220 may be performed. The vertical holes 320 may be formed, for example, by the first and second etching processes S210 and S220. In other example embodiments, the first and second etching processes S210 and S220 may be alternately and repeatedly performed to form the vertical holes 320. The substrate 100 may be unloaded from the process chamber 510 after the formation of the vertical holes 320 (S230). A portion 310r of the mask layer may remain after the formation of the vertical holes 320.

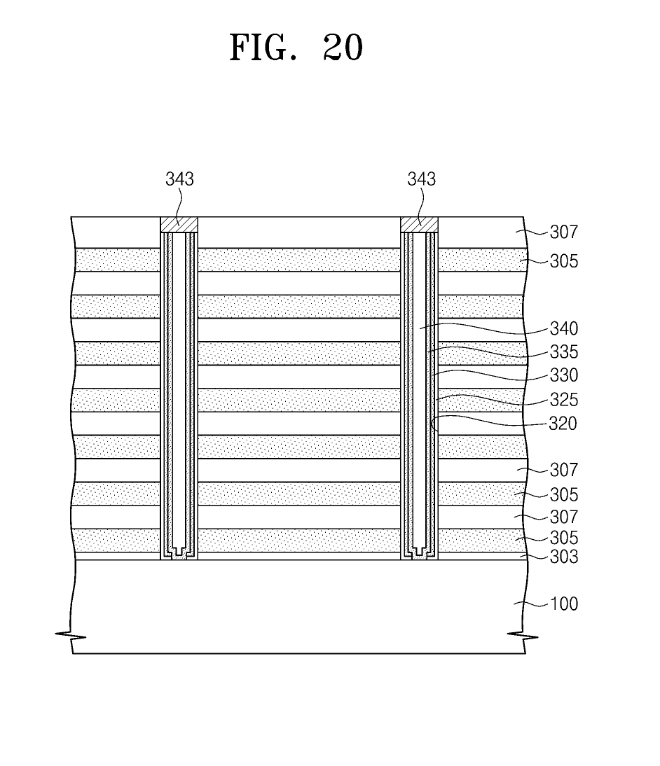

Referring to FIG. 20, the remaining mask layer 310r may be removed. A first sub-data storage layer may be conformally formed on the substrate 100 having the vertical holes 320, and a first semiconductor layer may be conformally formed on the first sub-data storage layer. The first semiconductor layer and the first sub-data storage layer may be anisotropically etched until the substrate 100 under the vertical holes 320 is exposed, thereby forming a first sub-data storage pattern 325 and a first semiconductor pattern 330 in each of the vertical holes 320. Subsequently, a second semiconductor layer may be conformally formed on the substrate 100, and a filling insulation layer may be formed on the second semiconductor layer to fill the vertical holes 320. The filling insulation layer and the second semiconductor layer may be planarized to form a second semiconductor pattern 335 and a filling insulation pattern 340 in each of the vertical holes 320.

The first semiconductor pattern 330 may be spaced apart from the substrate 100 by the first sub-data storage pattern 325, and the second semiconductor pattern 335 may be in contact with the substrate 100 and the first semiconductor pattern 330. The first and second semiconductor patterns 330 and 335 may constitute a vertical channel pattern.

Top ends of the first and second semiconductor patterns 330 and 335, the filling insulation pattern 340 and the first sub-data storage pattern 325 may be recessed, and the conductive pad 343 may be formed in the recessed region. The conductive pad 343 may be in contact with the first and second semiconductor patterns 330 and 335.

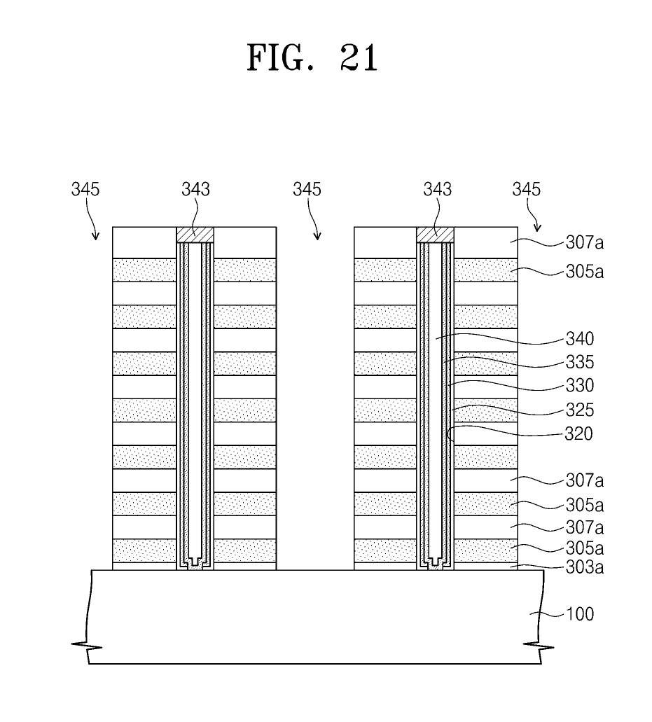

Referring to FIG. 21, the layers 307, 305, and 303 may be patterned to form trenches 345. A mold stack may be formed between the trenches 345 adjacent to each other. The mold stack may include a buffer insulating pattern 303a, sacrificial patterns 305a and insulating patterns 307a. The sacrificial patterns 305a and the insulating patterns 307a may be alternately and repeatedly stacked on the buffer insulating pattern 303a. An etching process used for the formation of the trenches 345 may be performed using the semiconductor fabricating apparatus 500 of FIG. 1 and/or the semiconductor fabricating apparatus 501 of FIG. 9. The vertical holes 320 may penetrate the mold stacks.

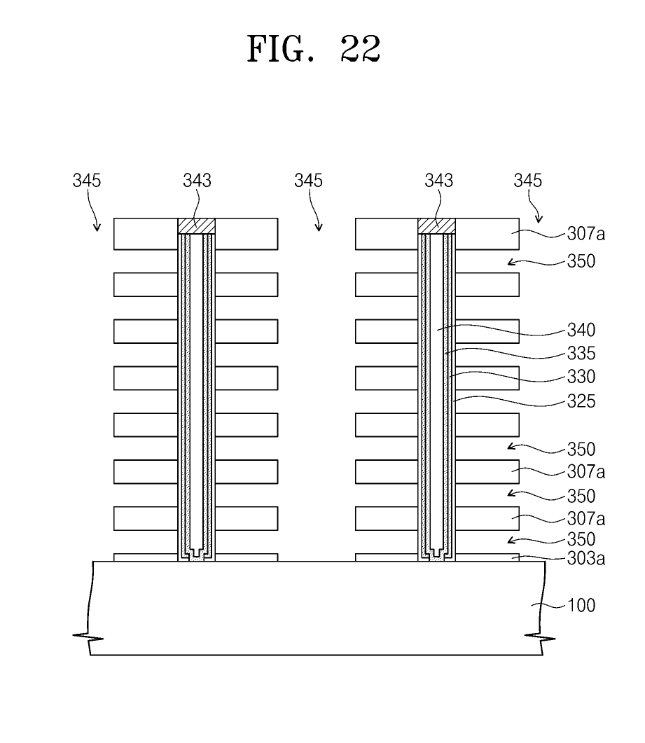

Referring to FIG. 22, the sacrificial patterns 305a may be removed to form empty regions 350. Each of the empty regions 350 may be disposed between the insulating patterns 307a which are vertically adjacent to each other.

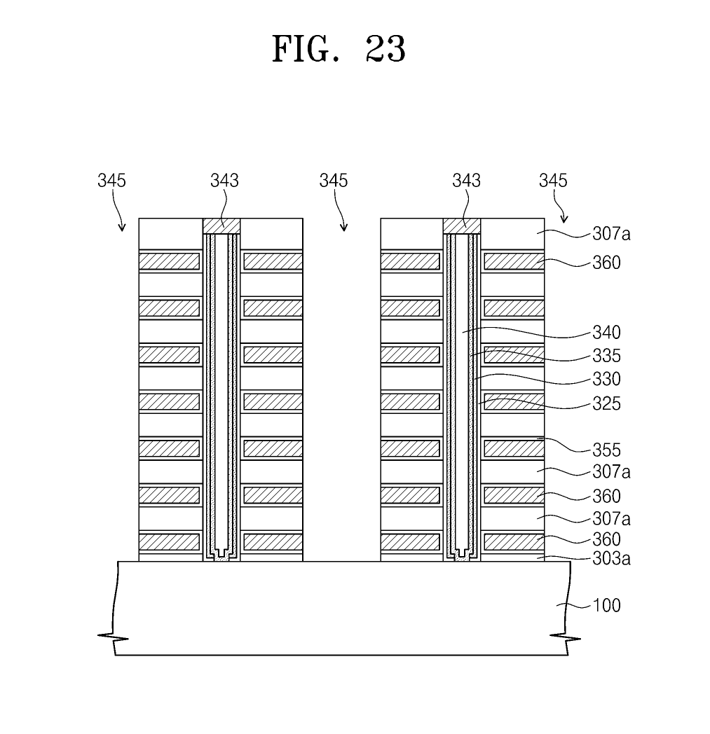

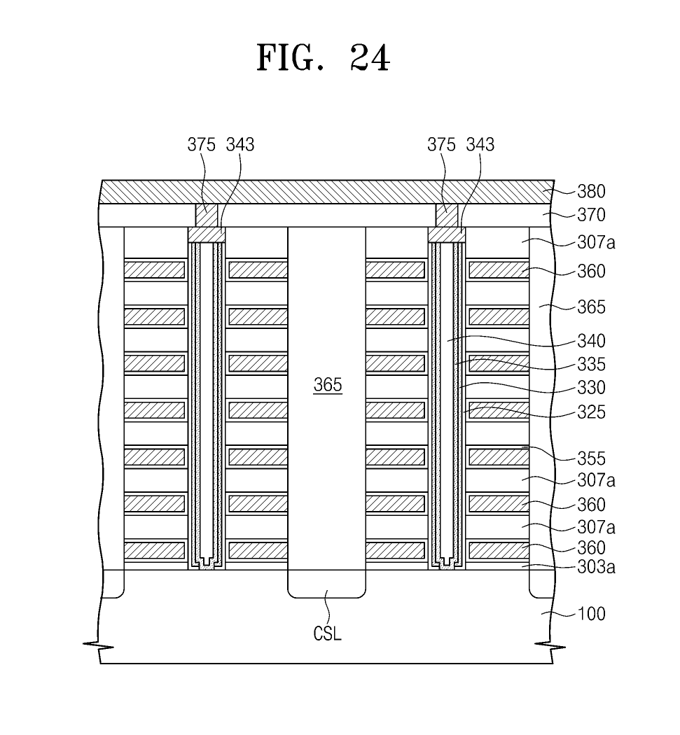

Referring to FIG. 23, a second sub-data storage layer may be conformally formed on inner surfaces of the empty regions 350, and a conductive layer may be formed on the second sub-data storage layer to fill the empty regions 350. The conductive layer disposed outside the empty regions 350 may be removed to form conductive patterns 360 in the empty regions 350. The second sub-data storage layer disposed outside the empty regions 350 may be removed to form a second sub-data storage pattern 355 between each of the conductive patterns 360 and the inner surface of each of the empty regions 350. In other embodiments, the second sub-data storage layer disposed outside the empty regions 350 may remain.

The conductive patterns 360 may be gate electrodes. The first and second sub-data storage patterns 325 and 355 may constitute a data storage pattern. The data storage pattern may include a tunnel dielectric layer, a charge storage layer, and a blocking dielectric layer. The blocking dielectric layer may include a barrier insulating layer and a high-k dielectric layer. An energy band gap of the barrier insulating layer may be greater than that of the high-k dielectric layer. A dielectric constant of the high-k dielectric layer may be greater than that of the tunnel dielectric layer. The first sub-data storage pattern 325 may include at least the tunnel dielectric layer. The second sub-data storage pattern 355 may include at least a portion of the blocking dielectric layer. Any one of the first and second sub-data storage patterns 325 and 355 may include the charge storage layer. In some embodiments, the first sub-data storage pattern 325 may include the tunnel dielectric layer, the charge storage layer, and the barrier insulating layer, and the second sub-data storage pattern 355 may include the high-k dielectric layer.

Referring to FIG. 24, a common source region CSL may be formed in the substrate 100 under each of the trenches 345, and a device isolation pattern 365 may be formed to fill each of the trenches 345. Subsequently, an interlayer insulating layer 370 may be formed on an entire top surface of the substrate 100, and contact plugs 375 may be formed to penetrate the interlayer insulating layer 370. The contact plugs 375 may be connected to the conductive pads 343, respectively. An interconnection 380 may be formed on the substrate 370 so as to be connected to the contact plugs 375. The interconnection 380 may be a bit line.

In some embodiments of the disclosure, the semiconductor manufacturing apparatus may use the low-frequency, high-frequency, and DC powers, synchronized with each other, to perform etching processes; the low-frequency power may have the non-sinusoidal waveform. Similarly, but in other embodiments of the disclosure, the semiconductor manufacturing apparatus may include both the first low-frequency power generator generating the first low-frequency power with the sinusoidal waveform and the second low-frequency power generator generating the second low-frequency power with the non-sinusoidal waveform. The above embodiments of the disclosure may improve the reliability and reproducibility of the etching processes used for forming openings having high aspect ratios. Thus, the reliability and reproducibility of the semiconductor devices may be improved.

While the disclosure has been described with reference to example embodiments, it will be apparent to those skilled in the art that various changes and modifications may be made without departing from the spirit and scope of the disclosure. Therefore, it should be understood that the above embodiments are not limiting, but illustrative. Thus, the scope of the disclosure is to be determined by the broadest permissible interpretation of the following claims and their equivalents, and shall not be restricted or limited by the foregoing description.

1. A semiconductor fabricating apparatus comprising:
a process chamber having an inner enclosed region in which a semiconductor process is performed;
a lower electrode disposed in the process chamber and having a top surface configured to load a substrate;
an upper electrode disposed over the lower electrode in the process chamber;
a low-frequency power generator connected to the lower electrode and configured to generate a low-frequency power having a non-sinusoidal waveform at a first frequency;
a high-frequency power generator configured to generate a high-frequency power having a second frequency higher than the first frequency of the low-frequency power;
a direct current (DC) power generator configured to generate a DC power comprised of a first period having a first level duration and a second level duration; and
a controller configured to provide a first control signal to the DC power generator, a second control signal to the low-frequency power generator, and a third control signal to the high-frequency power generator, the first control signal being applied to control the DC power generator to apply a first DC voltage to the upper electrode during the first level duration and to apply a second DC voltage different from the first DC voltage to the upper electrode during the second level duration, the second control signal being applied to control the low-frequency power generator to apply the low frequency power during the first level duration but not during the second level duration, and the third control signal being applied to control the high-frequency generator to apply the high frequency power during the first level duration but not during the second level duration.

2. The semiconductor fabricating apparatus of claim 1, further comprising:
a blocking capacitor connected between the lower electrode and the low-frequency power generator and between the lower electrode and the high-frequency power generator,
wherein the low-frequency power generator and the high-frequency power generator are connected to the lower electrode through the blocking capacitor, and
wherein the semiconductor process is an etching process.

3. The semiconductor fabricating apparatus of claim 1, wherein a second period of the low-frequency power has a first transition duration, a low-level duration, a second transition duration, and a high-level duration,
wherein a low-level voltage is applied during the low-level duration, and a high-level voltage higher than the low-level voltage is applied during the high-level duration, and
wherein a length of the low-level duration is different from a length of the high-level duration.

4. The semiconductor fabricating apparatus of claim 3, wherein the low-level voltage is constant during the low-level duration.

5. The semiconductor fabricating apparatus of claim 3, wherein the low-level voltage is gradually varied during the low-level duration.

6. The semiconductor fabricating apparatus of claim 1, wherein the first and second DC voltages are negative voltages, and
wherein the second DC voltage is lower than the first DC voltage.

7. The semiconductor fabricating apparatus of claim 1, further comprising:
a band-pass filtering unit connected between the low-frequency power generator and the lower electrode; and
a low-frequency matching unit connected between the band-pass filtering unit and the lower electrode,
wherein the band-pass filtering unit comprises a plurality of band-pass filters,
wherein each of the band-pass filters comprises a coil and a capacitor that are connected in series to each other,
wherein the capacitors of the band-pass filters have capacitance values different from each other, and
wherein the low-frequency matching unit comprises a plurality of matching circuits, each of which is connected to corresponding ones of the plurality of band-pass filters.

8. The semiconductor fabricating apparatus of claim 1, wherein the control signals of the controller synchronize the low-frequency power, high-frequency power, and direct current (DC) power to turn-on and turn-off at substantially the same time, and
wherein the first level duration is different than the second level duration.

9. The semiconductor fabricating apparatus of claim 3, wherein the low-level duration is between two and four times as long as the high-level duration.

10. A semiconductor fabricating apparatus comprising:
a process chamber;
a lower electrode disposed in the process chamber and having a top surface configured to load a substrate;
an upper electrode disposed over the lower electrode in the process chamber;
a first low-frequency power generator connected to the lower electrode and configured to generate a first low-frequency power having a sinusoidal waveform;
a second low-frequency power generator connected to the lower electrode and configured to generate a second low-frequency power having a non-sinusoidal waveform;
a high-frequency power generator configured to generate a high-frequency power of which a frequency is higher than frequencies of the first and second low-frequency powers; and
a controller configured to control the high-frequency power generator, the first low-frequency power generator and the second low-frequency power generator to generate the high-frequency power to generate plasma over the lower electrode concurrently with at least one of the first low-frequency power generator generating the first low-frequency power and the second low-frequency power generator generating the second low-frequency power.

11. The semiconductor fabricating apparatus of claim 10, wherein the controller is configured to interrupt application of the first low-frequency power by the first low-frequency power generator with the application of the second low-frequency power by the second low-frequency power generator.

12. The semiconductor fabricating apparatus of claim 11, wherein the controller is configured to control the first low-frequency power generator to generate the first low-frequency power for a first etching process, and to control the second low-frequency power generator to generate the second low-frequency power for a second etching process, and
wherein the first and second etching processes are performed in-situ in the process chamber.

13. The semiconductor fabricating apparatus of claim 11, further comprising:
a blocking capacitor connected between the lower electrode and the first low-frequency power generator, between the lower electrode and the second low-frequency power generator, and between the lower electrode and the high-frequency power generator,
wherein the first low-frequency power generator, the second low-frequency power generator, and the high-frequency power generator are connected to the lower electrode through the blocking capacitor.

14. The semiconductor fabricating apparatus of claim 10, further comprising:
a direct current (DC) power generator configured to generate a DC power having a first period comprised of a first level duration and a second level duration concurrent with each of the first and second low-frequency power generators generating first and second low-frequency powers, respectively,
wherein the controller is configured to have the DC power generator apply a first DC voltage to the upper electrode during the first level duration and to apply a second DC voltage different from the first DC voltage to the upper electrode during the second level duration.

15. The semiconductor fabricating apparatus of claim 14, wherein the controller is configured to control the first low-frequency power generator to turn-on the first low-frequency power during the first level duration and to not apply the first low-frequency power during the second level duration, and to control the high-frequency power generator to turn-on the high-frequency power during the first level duration and to not apply the high-frequency power during the second level duration.

16. The semiconductor fabricating apparatus of claim 10, wherein a period of the second low-frequency power has a first transition duration, a low-level duration, a second transition duration, and a high-level duration,
wherein a linear low-level voltage is applied to the substrate during the low-level duration, and a linear high-level voltage, higher than the linear low-level voltage, is linearly applied to the substrate during the high-level duration, and
wherein a time length of the low-level duration is different from a time length of the high-level duration.

17. The semiconductor fabricating apparatus of claim 10, further comprising:
a band-pass filtering unit connected between the second low-frequency power generator and the lower electrode; and
matching circuitry connected between the band-pass filtering unit and the lower electrode,
wherein the band-pass filtering unit comprises a plurality of band-pass filters,
wherein each of the band-pass filters comprises a coil and a capacitor that are connected in series to each other,
wherein the capacitors of the band-pass filters have capacitance values different from each other, and
wherein the matching circuitry comprises a plurality of matching circuits, each of which is connected to corresponding ones of the plurality of band-pass filters.

18. The semiconductor fabricating apparatus of claim 16,
wherein the linear low-level voltage is a negative voltage, and
wherein the linear high-level voltage is a positive voltage.

19. The semiconductor fabricating apparatus of claim 17, further comprising:
a fast Fourier transform circuit connected between the second low-frequency power generator and the band-pass filtering unit.

20. The semiconductor fabricating apparatus of claim 10, wherein the lower electrode further comprises an electrostatic chuck (ESC), and
wherein the upper electrode further comprises a shower head.

21-32. (canceled)
